(19) United States
(12) Patent Application Publication
(10) Pub. No.: US 2021/0010140 A1
(43) Pub. Date: Jan. 14, 2021

(54) DRY ETCHING METHOD FOR FILM LAYER STRUCTURE AND FILM LAYER STRUCTURE

(71) Applicant: TCL China Star Optoelectronics Technology Co., Ltd., Shenzhen, Guangdong (CN)

(72) Inventors: Chong HU, Shenzhen, Guangdong (CN); Xianwang WEI, Shenzhen, Guangdong (CN)

(21) Appl. No.: 16/616,498

(22) PCT Filed: Nov. 14, 2019
(86) PCT No.: PCT/CN2019/118443

§ 371 Date: Nov. 25, 2019

(30) Foreign Application Priority Data
Jul. 12, 2019 (CN) 201910630354.7

(51) Int. Cl. C23F 4/00; G03F 7/00

(52) U.S. Cl. CPC C23F 4/00; G03F 7/0002

(57) ABSTRACT

A film layer structure and a dry etching method for the film layer structure are provided. The dry etching method for the film layer structure includes the following steps. A step S1, a substrate is provided, and a thin film to be etched is formed on the substrate. A step S2, a photoresist material is coated at an intermediate portion of the thin film to be etched. A step S3, a dry etching is performed on the thin film to be etched to form one step portion. A step S4, an ashing treatment is performed on the thin film after the dry etching in the step S3 to degrade a portion of the photoresist.

### FIELD OF INVENTION

The invention relates to a display panel manufacturing technology, and particularly relates to a film layer structure and a dry etching method for the film layer structure.

### BACKGROUND OF INVENTION

Dry etching mainly etches in an anisotropic manner, and the loss of strip width is small. However, it is also easy to cause a section inclination to be too large, resulting in an overhead in the subsequent film formation. For the case where the section inclination is large and the film layer is thick, it is particularly likely to cause a fault in the subsequent film formation.

The reason why the section inclination is too large leads to the fault in the subsequent film formation is mainly that the force in the vertical direction of the thin film is greater than the fracture toughness it can withstand. The relevant force analysis is as shown in FIG. 1. Two parts that are prone to fracture are the stress concentration point of the thin film at A section of the overhead layer and two end points of the thin film at B section (stress concentration points). For the force analysis of barycenter of the thin film at A section, it is subjected to the gravity F=mg in a direction parallel to the thin film F1=mg sin θ and in a direction vertical to the thin film F2=mg cos θ, wherein when F2 is too large, the faults will occur in the area where the fracture toughness of the thin film at A section is poor. For the force analysis of the end points at B section, it is subjected to F1 in a direction vertical to the thin film F3=mg sin² θ and in a direction parallel to the thin film F4=mg sin θcos θ, wherein F4 is balanced by the friction in the parallel direction to the thin film, and the faults will occur at the end points at B section when F3 is too large. It can be seen that, F2 and F3 are the key forces leading to the fracture of the thin film, and these two forces are positively correlated with the gravity.

### SUMMARY OF INVENTION

### Technical Problems

The prior art dry etching is mainly etched in the anisotropic manner, and the loss of strip width is small. However, it is also easy to cause the section inclination to be too large, resulting in the overhead in the subsequent film formation. For the case where the section inclination is large and the film layer is thick, it is particularly likely to cause the faults in the subsequent film formation.

### Technical Solutions

To solve the above technical problems, a film layer structure and a dry etching method for the film layer structure are provided.

A dry etching method for a film layer structure includes the following steps.

A step S1, a substrate is provided, and a thin film is formed on the substrate.

A step S2, a photoresist material is coated at an intermediate portion of the thin film.

A step S3, a dry etching is performed on the thin film.

A step S4, an ashing treatment is performed on the thin film after the dry etching in the step S3 to degrade a portion of the photoresist material.

A step S5, the step S3 and the step S4 are repeated several times to form a plurality of step portions.

A step S6, the photoresist material is peeled off.

A step S7, a film layer is covered on the step portions and the substrate.

The thin film in the step S1 is a silicon oxide thin film or a silicon nitride thin film.

The thin film in the step S1 is a molybdenum thin film or an aluminum thin film.

According to the dry etching method for the film layer structure provided by the embodiment of the present invention, a gas used in the ashing treatment in the step S4 includes pure oxygen.

According to the dry etching method for the film layer structure provided by the embodiment of the present invention, the gas used in the ashing treatment includes a mixed gas containing oxygen.

According to the dry etching method for the film layer structure provided by the embodiment of the present invention, the several times in the step S5 are at least 2 to 6 times.

According to the dry etching method for the film layer structure provided by the embodiment of the present invention, the step portions in the step S5 are at least 2 to 6 step portions, and the step portions have the same height.

The embodiment of the present invention further provides a dry etching method for a film layer structure including the following steps.

A step S1, a substrate is provided, and a thin film is formed on the substrate.

A step S2, a photoresist material is coated at an intermediate portion of the thin film.

A step S3, a dry etching is performed on the thin film.

A step S4, an ashing treatment is performed on the thin film after the dry etching in the step S3 to degrade a portion of the photoresist material.

A step S5, the step S3 and the step S4 are repeated several times to form a plurality of step portions.

A step S6, the photoresist material is peeled off.

A step S7, a film layer is covered on the step portions and the substrate.

According to the dry etching method provided by the embodiment of the present invention, the thin film in the step S1 is a silicon oxide thin film or a silicon nitride thin film.

According to the dry etching method for the film layer structure provided by the embodiment of the present invention, the thin film in the step S1 is a molybdenum thin film or an aluminum thin film.

According to the dry etching method for the film layer structure provided by the embodiment of the present invention, a gas used in the ashing treatment in the step S4 includes pure oxygen.

According to the dry etching method for the film layer structure provided by the embodiment of the present invention, the gas used in the ashing treatment includes a mixed gas containing oxygen.

According to the dry etching method for the film layer structure provided by the embodiment of the present invention, the several times in the step S5 are at least 2 to 6 times.

According to the dry etching method for the film layer structure provided by the embodiment of the present invention, the step portions in the step S5 are at least 2 to 6 step portions, and the step portions have the same height.

The embodiment of the present invention further provides a display panel including a base substrate, a plurality of step portions, and a film layer. The step portions are formed on the base substrate, and the film layer covers the step portions and the base substrate.

According to the display panel provided by the embodiment of the present invention, the step portions are composed of at least one of a metal thin film, a nonmetallic oxide, and a nonmetallic nitride.

According to the display panel provided by the embodiment of the present invention, the step portions are at least 2 to 6 step portions, and the step portions have the same height.

### Beneficial Effects

The invention provides a dry etching method and a film layer structure, which can divide the section inclination edge into a plurality of step portions by step etching with the effect of dry etching and photoresist, and the gravity force of each step portion of the thin film is reduced, thereby reducing the force of the two sections of the thin film in the vertical direction and reducing the risk of the fault in the film formation.

### DESCRIPTION OF DRAWINGS

FIG. 1 is a schematic diagram showing the force analysis of a film layer structure in the prior art.

FIG. 2 is a schematic diagram of a dry etching method according to an embodiment of the present invention.

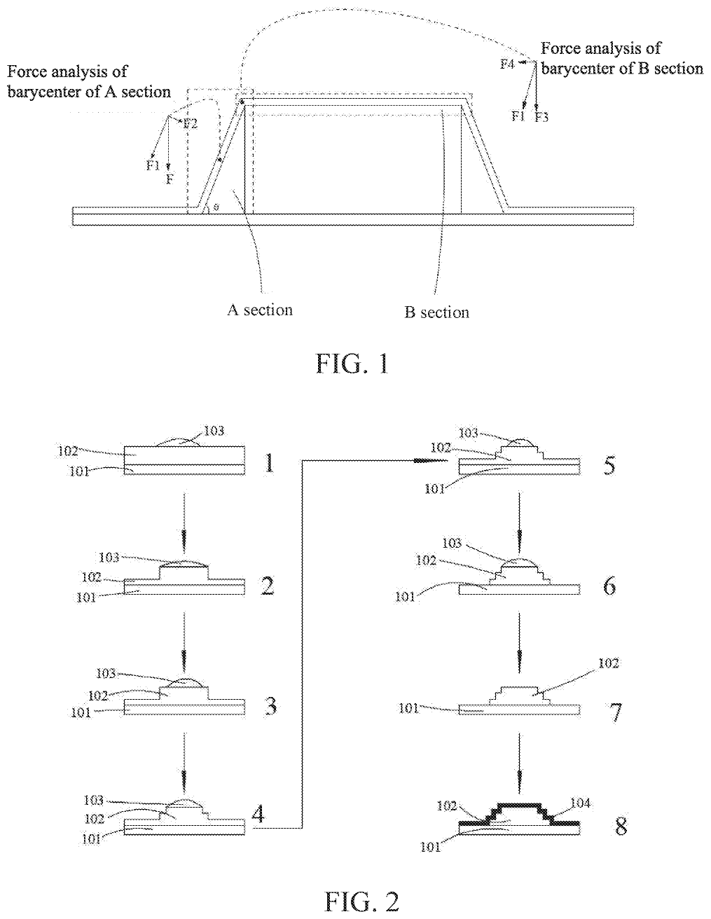

### DETAILED DESCRIPTION OF PREFERRED EMBODIMENTS

The detailed description of the following embodiments is used for exemplifying the specific embodiments of the present disclosure by referring to the accompany drawings.

The structure and the technical means adopted by the present disclosure to achieve the above and other objects can be best understood by referring to the following detailed description of the preferred embodiments. Furthermore, directional terms described by the present disclosure, such as upper, lower, front, back, left, right, inner, outer, side, etc., are only directions by referring to the accompanying drawings, and thus the directional terms are used to describe and understand the present invention, but the present invention is not limited thereto.

In the drawings, structure-like elements are labeled with like reference numerals.

The invention is directed to the film layer structure in the prior art. The section inclination of the film layer after dry etching is large, which leads to the fault in the subsequent film formation. The present embodiment can solve the defect.

The present invention provides a dry etching method for a film layer structure including the following steps.

A step S1, a substrate is provided, and a thin film to be etched is formed on the substrate.

Particularly, the thin film to be etched in the present process in the step S1 may be composed of at least one of a nonmetallic oxide, a nonmetallic nitride, and a metal. The nonmetallic oxide is silicon oxide, etc., the nonmetallic nitride is silicon nitride, etc., and the metal is molybdenum, aluminum, and other metals.

A step S2, a photoresist material is coated at an intermediate portion of the thin film to be etched.

A step S3, a dry etching is performed on the thin film to be etched to form one step portion.

Particularly, after the steps S1 and S2 are performed, the thin film to be etched is subjected to dry etching once, and the step portion is formed around the photoresist.

A step S4, an ashing treatment is performed on the thin film after the dry etching in the step S3 to degrade a portion of the photoresist.

Particularly, a gas used in the ashing treatment in the step S4 includes, but is not limited to, pure oxygen. The gas used in the ashing treatment includes a mixed gas containing oxygen capable of ashing the photoresist.

A step S5, the steps S3 and S4 are repeated several times to form a plurality of step portions.

A step S6, the photoresist material is peeled off.

A step S7, a film layer is covered on the step portions and the substrate.

Particularly, as shown in FIG. 2, a schematic diagram of a dry etching method for a film layer structure provided by the present embodiment is shown.

In the present embodiment, the several times are set to two times. That is, three steps are formed.

As shown in FIG. 2, the substrate 101 in the step 1 is subjected to a previous manufacturing process, and then the film formation and photoresist coating, exposure development of the present process are completed on the substrate 101. A thin film 102 and a photoresist layer 103 of the present process are formed on the substrate, and then the dry etching stage is entered. The step 2 is the first dry etching of the thin film 102, and the thin film 102 forms one step portion. The step 3 is the first ashing treatment of the thin film 102, and a portion of the photoresist layer 103 is degraded. The step 4 is the second dry etching of the thin film 102, and the thin film 102 forms two step portions. The step 5 is the second ashing treatment of the thin film 102, and a portion of the photoresist layer 103 is degraded again. The step 6 is the third dry etching of the thin film 102, and the thin film 102 forms three step portions. The step 7 is to peel off the photoresist layer 103. The step 8 is to cover a subsequent film layer 104 on the three step portions of the thin film 102 and the substrate 101.

The operation times of the above three dry etchings are the same, and the operation time of each dry etching is one third of the total etching time required. If the film layer 102 is divided into n step portions, each etching time is one-nth of the total etching time required. Thus, in the present embodiment, the three step portions have the same height.

The present embodiment also provides a display panel using the dry etching method provided by the above embodiment. The display panel includes a base substrate, a plurality of step portions after the dry etching, and a film layer. The step portions are formed on the base substrate, and the film layer covers the step portions and the base substrate. The step portions are composed of at least one of a metal thin film, a nonmetallic oxide, and a nonmetallic nitride. The step portions are at least 2 to 6 step portions, and the step portions have the same height.

In the embodiment of the present invention, the original section inclination is divided into three step portions using the step dry etching. Thus, the force of the original section inclination is reduced to one third, and the probability of generating the fault is reduced to one third of the original.

Although with respect to one or more implementations shown and described the present disclosure, those skilled in the art based upon a reading and understanding of this specification and the drawings will occur equivalent variations and modifications. The present disclosure includes all such variations and modifications, and is limited only by the limits of the appended claims. In particular regard to the various functions performed by the above described components, the terms used to describe such components are intended to correspond to the execution of the functions specified component (e.g., that is functionally equivalent) of any component (unless otherwise indicated) discloses the structure and function even in the structure shown herein to achieve the implementation of an exemplary embodiment of the present specification is not equivalent. In addition, while a particular feature of this specification has been disclosed with respect to only one of several implementations, such feature may be as for a given or particular application desired and advantageous implementations of one or more other other combinations of features. Also, the terms “comprising”, “having”, “containing”, or variants thereof are used in the detailed description or the claims, such a term is intended to the term “comprising” include similar manner.

The above is only a preferred embodiment of the present disclosure, and it should be noted that those skilled in the art can make several improvements and refinements without departing from the principles of the present disclosure. These improvements and refinements should also be regarded as the scope of protection of the present disclosure.

What is claimed is:

1. A dry etching method for a film layer structure, comprising:
a step S1 of providing a substrate and forming a thin film on the substrate;
a step S2 of coating a photoresist material at an intermediate portion of the thin film;
a step S3 of performing a dry etching on the thin film;
a step S4 of performing an ashing treatment on the thin film after the dry etching in the step S3 to degrade a portion of the photoresist material;
a step S5 of repeating the step S3 and the step S4 several times to form a plurality of step portions;
a step S6 of peeling off the photoresist material; and
a step S7 of covering a film layer on the step portions and the substrate;
wherein the thin film in the step S1 is a silicon oxide thin film or a silicon nitride thin film; and
wherein the thin film in the step S1 is a molybdenum thin film or an aluminum thin film.

2. The dry etching method for the film layer structure according to claim 1, wherein a gas used in the ashing treatment in the step S4 comprises pure oxygen.

3. The dry etching method for the film layer structure according to claim 2, wherein the gas used in the ashing treatment comprises a mixed gas containing oxygen.

4. The dry etching method for the film layer structure according to claim 1, wherein the several times in the step S5 are at least 2 to 6 times.

5. The dry etching method for the film layer structure according to claim 4, wherein the step portions in the step S5 are at least 2 to 6 step portions, and the step portions have the same height.

6. A dry etching method for a film layer structure, comprising:
a step S1 of providing a substrate and forming a thin film on the substrate;
a step S2 of coating a photoresist material at an intermediate portion of the thin film;
a step S3 of performing a dry etching on the thin film;
a step S4 of performing an ashing treatment on the thin film after the dry etching in the step S3 to degrade a portion of the photoresist material;
a step S5 of repeating the step S3 and the step S4 several times to form a plurality of step portions;
a step S6 of peeling off the photoresist material; and
a step S7 of covering a film layer on the step portions and the substrate.

7. The dry etching method for the film layer structure according to claim 6, wherein the thin film in the step S1 is a silicon oxide thin film or a silicon nitride thin film.

8. The dry etching method for the film layer structure according to claim 6, wherein the thin film in the step S1 is a molybdenum thin film or an aluminum thin film.

9. The dry etching method for the film layer structure according to claim 6, wherein a gas used in the ashing treatment in the step S4 comprises pure oxygen.

10. The dry etching method for the film layer structure according to claim 9, wherein the gas used in the ashing treatment comprises a mixed gas containing oxygen.

11. The dry etching method for the film layer structure according to claim 6, wherein the several times in the step S5 are at least 2 to 6 times.

12. The dry etching method for the film layer structure according to claim 11, wherein the step portions in the step S5 are at least 2 to 6 step portions, and the step portions have the same height.

13. A display panel, comprising a base substrate, a plurality of step portions, and a film layer, wherein the step portions are formed on the base substrate, and the film layer covers the step portions and the base substrate.

14. The display panel according to claim 13, wherein the step portions are composed of at least one of a metal thin film, a nonmetallic oxide, and a nonmetallic nitride.

15. The display panel according to claim 14, wherein the step portions are at least 2 to 6 step portions, and the step portions have the same height.
